(19) United States
(12) Patent Application Publication
(10) Pub. No.: US 2025/0085361 A1
(43) Pub. Date: Mar. 13, 2025

(54) MAGNETIC FIELD SENSOR CIRCUIT AND MAGNETIC FIELD MEASUREMENT METHOD

(71) Applicant: Infineon Technologies AG, Neubiberg (DE)

(72) Inventors: Christoph KRALL, Klagenfurt (AT); Carlos Humberto GARCIA ROJAS, Villach (AT); Johannes GUETTINGER, Lind ob Velden (AT)

(21) Appl. No.: 18/830,886

(22) Filed: Sep. 11, 2024

(30) Foreign Application Priority Data
Sep. 12, 2023 (DE) 102023124593.7

(51) Int. Cl. G01R 33/00; G01R 33/09

(52) U.S. Cl. CPC G01R 33/0023; G01R 33/093; G01R 33/098; G01R 33/0005

(57) ABSTRACT

The present disclosure relates to magnetic field sensor circuit which includes a first bridge circuit including a first series connection of a first magneto-resistor and a second magneto-resistor, and a second bridge circuit including a second series connection of a third magneto-resistor and a fourth magneto-resistor. A first terminal between the first magneto-resistor and the second magneto-resistor of the first bridge circuit is coupled to a second terminal between the third magneto-resistor and the fourth magneto-resistor of the second bridge circuit. The coupled first and second terminals provide a first output signal of the magnetic field sensor circuit.

### CROSS-REFERENCE TO RELATED APPLICATION

This application claims priority to Germany Patent Application No. 102023124593.7 filed on Sep. 12, 2023, the content of which is incorporated by reference herein in its entirety.

### TECHNICAL FIELD

The present disclosure generally relates to magnetic field sensors, and, more particularly, to magnetic field sensors for differential field sensing and homogeneous field sensing.

### BACKGROUND

In current sensing with internal and external bus bars (or current rails), it is common to try to place sensing elements in such an arrangement that a first sensing element is placed above the bus bar and a second sensing element is placed adjacent to the first sensing element. This allows the current sensor to differentially sense the electrical current in the bus bar. With the differential sensing architecture, the current sensor may be very robust to any homogeneous stray field present in the current sensing application. However, there may be sensing arrangements where it is preferable to be sensitive to homogeneous fields (e.g., in core based current sensing or for linear torque sensing).

Another application is magnetic speed sensing where differential and/or mono-mode sensing is used to detect the speed and direction of rotation of a toothed ferrite wheel or a wheel with magnetic domains. As an example, a dynamic switching between mono-mode and differential-mode reading in Giant Magnetoresistance (GMR) was implemented by measuring the resistance drop across part of a Wheatstone bridge in mono-mode. In addition to the drawback that no Wheatstone bridge readout could be used for the mono mode, the approach is even not feasible for Tunnel Magnetoresistance (TMR) devices because the field sensitivity is proportional to conductance rather than resistance in GMR. In addition, it is difficult to adjust the gain if the sensitivities in the two modes do not match.

Usually the sensing concept has to be chosen beforehand and must be defined at the beginning of a sensor design. Once the architecture is chosen, the overall design attempts to optimize either the differential signal capabilities or the homogeneous sensing capabilities. In addition, it is not easy to create a concept that is flexible and to have this choice made by a simple configuration bit or metal mask configuration without a lot of circuit overhead.

State of the art is to choose a sensing principle at the outset and then optimize the architecture to fit the application perfectly. This approach is very inflexible when it turns out that some applications may have a different need. This is even more of a problem if the application requires both modes at the same time. This would require two sensors in different configurations, making it impossible to scale the solution and adding cost.

Thus, there is a need to provide more flexible approaches to current sensing.

### SUMMARY

This need is addressed by magnetic field sensor circuits and magnetic field sensing methods in accordance with the appended claims.

According to a first aspect, the present disclosure proposes a magnetic field sensor circuit. The magnetic field sensor circuit includes a first bridge circuit which includes a first series connection of a first magneto-resistor and a second magneto-resistor. The magnetic field sensor circuit further includes a (separate) second bridge circuit including a second series connection of a third magneto-resistor and a fourth magneto-resistor. A first terminal between the first and the second magneto-resistor of the first bridge circuit is coupled to a second terminal between the third and the fourth magneto-resistor of the second bridge circuit. The coupled first and second terminals provide a first output signal of the magnetic field sensor circuit. The first and second terminal may be short circuited. In this way, a magnetic field or current sensor with at least single-ended output signal may be provided for both differential and homogeneous field sensing.

The first and the second bridge circuit may be separate full or half Wheatstone bridges, respectively. The magnetic field sensor circuit may be implemented using discrete components or as one or more integrated circuits (ICs).

In some implementations, the first magneto-resistor of the first bridge circuit includes a first reference magnetization. The second magneto-resistor of the first bridge circuit includes a second reference magnetization different from the first reference magnetization. The third magneto-resistor of the second bridge circuit includes the second reference magnetization (of the second magneto-resistor). The fourth magneto-resistor of the second bridge circuit includes the first reference magnetization (of the first magneto-resistor).

In some implementations, the second reference magnetization is antiparallel to the first reference magnetization. Thus, the second reference magnetization is shifted by 180° to the first reference magnetization.

In some implementations, the first series connection of the first bridge circuit is coupled between a first power supply terminal and a first ground terminal. The second series connection of the second bridge circuit is coupled between a second supply terminal and a second ground terminal. While the first and second power supply terminals may refer to separate terminals, they also may refer to one common power supply terminal. Likewise, while the first and second ground terminals may refer to separate terminals, they also may refer to one common ground terminal.

In some implementations, the first power supply terminal is coupled to a magneto-resistor of the first series connection having the first reference magnetization and the second power supply terminal is coupled to a magneto-resistor of the second series connection having the second reference magnetization different from the first reference magnetization. Here, the power supply is connected to magneto-resistors of the first and second series connection having different reference magnetizations. Such a configuration may provide sensitivity of the magnetic field sensor circuit for differential field sensing.

In some implementations, the first power supply terminal is coupled to a magneto-resistor of the first series connection (of the first bridge circuit) having the first reference magnetization and the second power supply terminal is coupled to a magneto-resistor of the second series connection (of the second bridge circuit) having the first reference magnetization. Here, the power supply is connected to magneto-resistors of the first and second series connection having the same reference magnetization. Such a configuration may provide sensitivity of the magnetic field sensor circuit for homogeneous field sensing.

In some implementations, the first series connection (of the first bridge circuit) of the first magneto-resistor and the second magneto-resistor is coupled between a first power supply terminal and a first ground terminal, and the second series connection (of the second bridge circuit) of the third magneto-resistor and the fourth magneto-resistor is coupled between a second ground terminal and a third ground terminal. Thus, while the first series connection (of the first bridge circuit) may be coupled between power supply and ground, the second series connection (of the second bridge circuit) may be coupled between two ground terminals. Such a configuration may provide sensitivity of the magnetic field sensor circuit for both differential and homogeneous field sensing.

In some implementations, the first series connection (of the first bridge circuit) of the first magneto-resistor and the second magneto-resistor is coupled between a power supply and ground. The magnetic field sensor circuit may further include a switch circuit which is configured to switch between different magnetic field sensing modes by modifying a power supply of the first second series connection (of the first bridge circuit) or of the second series connection (of the second bridge circuit).

In some implementations, the switch circuit is configured to, in a first sensing mode, couple the second series connection of the third magneto-resistor and the fourth magneto-resistor between the power supply and ground, in a second sensing mode, switch the terminals of power supply and ground for the second series connection compared to the first sensing mode, and/or in a third sensing mode, couple the second series connection of the third magneto-resistor and the fourth magneto-resistor between two ground terminals. In this way, the magnetic field sensor circuit may be configured for different sensing modes for differential and/or homogeneous field sensing.

In some implementations, the first bridge circuit includes a third series connection of a fifth magneto-resistor and a sixth magneto-resistor connected in parallel to the first series connection. Thus, the first bridge circuit may be a full Wheatstone bridge circuit. The second bridge circuit includes a fourth series connection of a seventh magneto-resistor and an eighth magneto-resistor connected in parallel to the second series connection. Thus, the second bridge circuit may be a full Wheatstone bridge circuit. A third terminal between the fifth and the sixth magneto-resistor of the first bridge circuit is coupled to a fourth terminal between the seventh and the eighth magneto-resistor of the second bridge circuit. The coupled third and fourth terminals may provide a second output signal of the magnetic field sensor circuit. The third and fourth terminal may be short circuited. In this way, a current sensor with a differential output signal may be provided.

In some implementations, the fifth magneto-resistor of the first bridge circuit includes the second reference magnetization (of the second magneto-resistor), the sixth magneto-resistor of the first bridge circuit includes the first reference magnetization (of the first magneto-resistor), the seventh magneto-resistor of the second bridge circuit includes the first reference magnetization, and the eighth magneto-resistor of the second bridge circuit includes the second reference magnetization.

In some implementations, the magnetic field sensor circuit further includes a difference amplifier. A first input terminal of the difference amplifier is coupled to the first output signal, and a second input terminal of the difference amplifier is coupled to the second output signal of the magnetic field sensor. The difference amplifier may be implemented as an Operational Amplifier (Op-Amp) or an Operational Transconductance Amplifier (OTA). The OTA is a specialized type of amplifier that provides an output current proportional to the difference between its input voltages. Unlike voltage amplifiers (operational amplifiers or op-amps), which provide an output voltage proportional to the input voltage difference, OTAs amplify the input voltage difference by converting it into an output current.

In some implementations, the magneto-resistors of the first and the second bridge circuits are Giant Magneto-resistors (GMR) or Tunnel Magneto-Resistors (TMR).

According to a further aspect, the present disclosure proposes a magnetic field measurement method. The method includes providing a first bridge circuit including a first series connection of a first magneto-resistor and a second magneto-resistor, providing a second bridge circuit including a second series connection of a third magneto-resistor and a fourth magneto-resistor, coupling a first terminal between the first and the second magneto-resistor of the first bridge circuit to a second terminal between the third and the fourth magneto-resistor of the second bridge circuit, and providing an output signal of the magnetic field sensor circuit at the coupled first and second terminals.

In some implementations, the first bridge circuit includes a third series connection of a fifth magneto-resistor and a sixth magneto-resistor connected in parallel to the first series connection. The second bridge circuit includes a fourth series connection of a seventh magneto-resistor and an eighth magneto-resistor connected in parallel to the second series connection. The method may further include coupling a third terminal between the fifth and the sixth magneto-resistor of the first bridge circuit to a fourth terminal between the seventh and the eighth magneto-resistor of the second bridge circuit, and providing a second output signal of the magnetic field sensor circuit at the coupled third and fourth terminals.

In some implementations, the first series connection of the first magneto-resistor and the second magneto-resistor may be coupled between a power supply and ground. The method may include switching between different sensing modes by modifying a power supply of the first and/or the second series connection.

In some implementations, switching between different sensing modes includes, in a first sensing mode, coupling the second series connection of the third magneto-resistor and the fourth magneto-resistor between the power supply and ground, in a second sensing mode, switching the terminals of power supply and ground for the second series connection compared to the first sensing mode, and/or in a third sensing mode, coupling the second series connection of the third magneto-resistor and the fourth magneto-resistor between two ground terminals.

The present disclosure proposes a dual bridge approach to address the differential sensing on a current rail. Furthermore, by grounding one of the bridges, one can switch to the other sensing mode and is sensitive to homogeneous fields. This could be done permanently, or even with a user command to allow measurement of both signals by a single sensor.

### BRIEF DESCRIPTION OF THE DRAWINGS

Some examples of apparatuses and/or methods will be described in the following by way of example only, and with reference to the accompanying figures, in which

FIGS. 1A-D show different magnetic sensing concepts for current sensing and speed sensing to which the present disclosure can be applied;

FIG. 2A shows a conventional sensor (full) bridge configuration;

FIG. 2B shows the conventional sensor bridge configuration of FIG. 2A coupled to a differential amplifier circuit;

FIG. 2C shows a conventional sensor (half) bridge configuration coupled to an amplifier circuit;

FIG. 3A shows a sensor bridge configuration according to a first implementation;

FIG. 3B shows a sensor bridge configuration according to a second implementation;

FIG. 3C shows a sensor bridge configuration according to a third implementation; and

FIG. 4 shows a sensor bridge configuration with amplifiers for output signal amplification.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

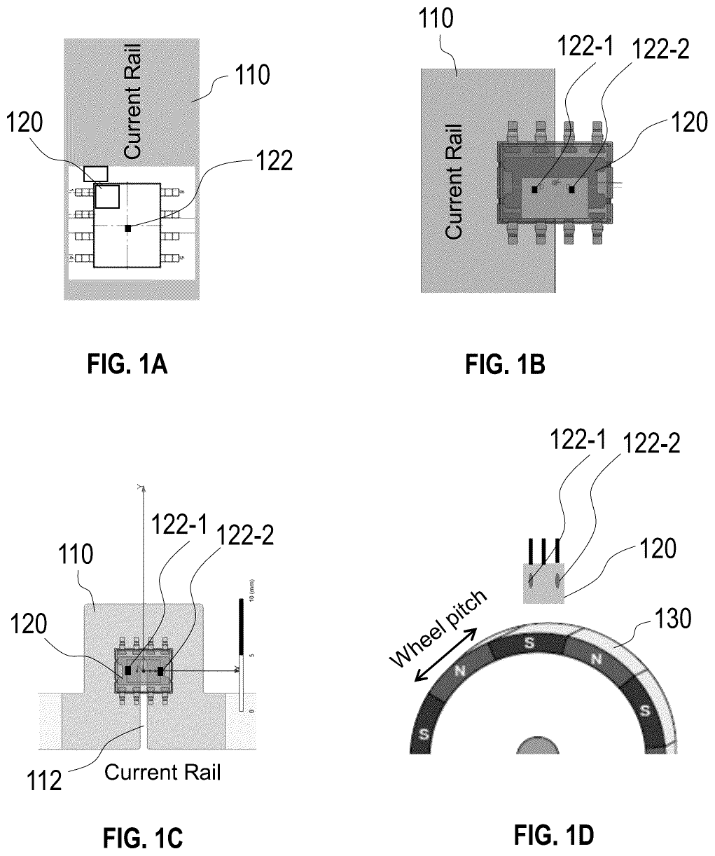

FIGS. 1A-D illustrate different magnetic sensing concepts for current sensing and speed sensing applications to which implementations of the present disclosure can be applied.

FIG. 1A shows a first current sensing concept with a current rail or bus bar 110 being arranged external to a sensor chip or IC (integrated circuit) 120. In FIG. 1A, sensor IC 120 comprises a single magnetic sensing element 122 and is arranged above the bus bar 110 for homogeneous magnetic field sensing. Sensing element 122 may comprise a (full) Wheatstone bridge arrangement of four magneto-resistors, for example. The magneto-resistors may also be referred to as XMR elements.

FIG. 1B shows a second current sensing concept with bus bar 110 being arranged external to sensor IC 120. Sensor IC 120 comprises a first sensing element 122-1 arranged above the bus bar 110 and a second sensing element 122-2 arranged adjacent to the first sensing element 122-1, and also adjacent to bus bar 110 for differential magnetic field sensing. Both sensing elements 122-1, 122-2 may comprise a respective (full) Wheatstone bridge arrangement of four magneto-resistors, for example.

FIG. 1C shows a third current sensing concept with bus bar 110 being arranged external to sensor IC 120. Sensor IC 120 comprises a first sensing element 122-1 arranged above the bus bar 110 and a second sensing element 122-2 arranged adjacent to the first sensing element 122-1 but also above bar 110 for differential magnetic field sensing. In the example of FIG. 1C, bus bar 110 comprises a slit 112 over which sensor IC 120 is placed. First sensing element 122-1 may measure the magnetic field due to the current through bus bar 110 left of slit 112, second sensing element 122-2 may measure the magnetic field due to the current through bus bar 110 right of slit 112. Both sensing elements 122-1, 122-2 may comprise a respective Wheatstone bridge arrangement of four magneto-resistors, for example.

FIG. 1D illustrates a magnetic speed sensing application where differential sensing is used to detect the speed and direction of rotation of a toothed ferrite wheel 130 or a wheel with magnetic domains. Sensor IC 120 is arranged radially outside the wheel 130 and comprises two adjacent sensing elements 122-1, 122-2 for differential field sensing. Both sensing elements 122-1, 122-2 may comprise a respective Wheatstone bridge arrangement of four magneto-resistors, for example.

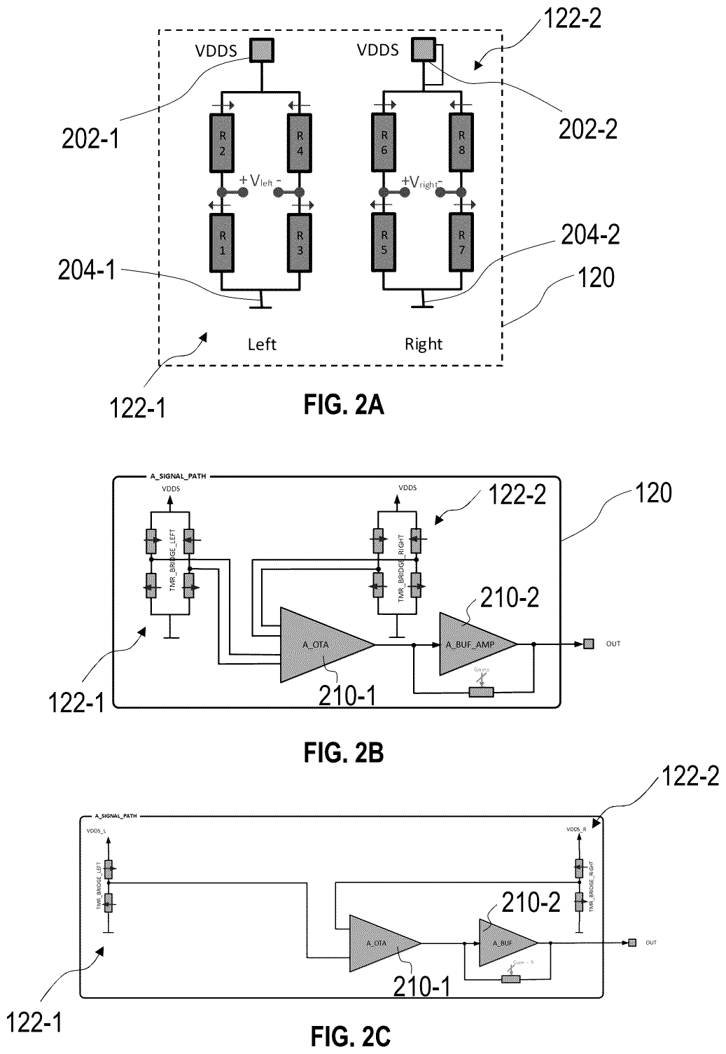

FIG. 2A illustrates a conventional sensor IC 120 with a first magnetic sensing element 122-1 implemented as first bridge circuit and an adjacent second magnetic sensing element 122-2 implemented as second bridge circuit. In the illustrated example, the first and the second bridge circuits 122-1, 122-2 are implemented as full Wheatstone bridges, respectively, for providing respective differential output signals V_{left} and V_{right}. The skilled person having benefit from the present disclosure will appreciate that the first and the second bridge circuits 122-1, 122-2 could also be implemented as half Wheatstone bridges if single-ended output signals are sufficient. While a half Wheatstone bridge merely consists of a single series connection of a first resistor and a second resistor, a full Wheatstone bridge comprises a first series connection of a first magneto-resistor and a second magneto-resistor connected in parallel to a second series connection of a third resistor and a fourth resistor.

The first bridge circuit 122-1 shown in FIG. 2A (left) comprises a first series connection of a first magneto-resistor R1 and a second magneto-resistor R2 coupled between a first power supply terminal 202-1 and a first ground terminal 204-1. The first power supply terminal 202-1 is directly coupled to second magneto-resistor R2. The first ground terminal 204-1 is directly coupled to first magneto-resistor R1. The first bridge circuit 122-1 further comprises a second series connection of a third magneto-resistor R3 and a fourth magneto-resistor R4 coupled between the first power supply terminal 202-1 and the first ground terminal 204-1 in parallel to the first series connection. The first power supply terminal 202-1 is directly coupled to fourth magneto-resistor R4. The first ground terminal 204-1 is directly coupled to third magneto-resistor R3.

The first magneto-resistor R1 comprises a first reference magnetization (here: to the left), the second magneto-resistor R2 comprises a second reference magnetization (here: to the right) different from the first reference magnetization. The second reference magnetization of the second magneto-resistor R2 may be antiparallel (e.g., 180°) to the first reference magnetization of the first magneto-resistor R1. The third magneto-resistor R3 comprises the second reference magnetization (to the right), and the fourth magneto-resistor R4 comprises the first reference magnetization (to the left). A first differential output signal (V_{left}) of the first bridge circuit 122-1 is provided between a first output terminal (V_{left}⁺) between the first and the second magneto-resistors R1, R2 and a second output terminal (V_{left}⁻) between the third and the fourth magneto-resistors R3, R4.

The second bridge circuit 122-2 shown in FIG. 2A (right) comprises a third series connection of a fifth magneto-resistor R5 and a sixth magneto-resistor R6 coupled between a second power supply terminal 202-2 and a second ground terminal 204-2. The second power supply terminal 202-2 is directly coupled to sixth magneto-resistor R6. The second ground terminal 204-2 is directly coupled to fifth magneto-resistor R5. The second bridge circuit 122-2 further comprises a fourth series connection of a seventh magneto-resistor R7 and an eighth magneto-resistor R8 coupled between the second power supply terminal 202-2 and the second ground terminal 204-2 in parallel to the third series connection. The second power supply terminal 202-2 is directly coupled to eighth magneto-resistor R8. The second ground terminal 204-2 is directly coupled to seventh magneto-resistor R7.

The fifth magneto-resistor R5 comprises the first reference magnetization (here: to the left), the sixth magneto-resistor R6 comprises the second reference magnetization (here: to the right) different from the first reference magnetization. The seventh magneto-resistor R7 comprises the second reference magnetization, and the eighth magneto-resistor R8 comprises the first reference magnetization. A second differential output signal (V_{right}) of the second bridge circuit 122-2 is provided between a third output terminal (V_{right}⁺) between the fifth and the sixth magneto-resistors R5, R6 and a fourth output terminal (V_{right}⁻) between the seventh and the eighth magneto-resistors R7, R8.

Magneto-resistors R1 to R8 are a type of electronic component whose electrical resistance changes in response to an applied external magnetic field. Some examples of magneto-resistors which may be used are:

Anisotropic Magnetoresistive (AMR) elements: AMR elements utilize the anisotropic magnetoresistance effect, where the electrical resistance of a material changes with the direction of an applied magnetic field. They are commonly used in magnetic field sensing applications, such as compasses, position sensors, and non-contact current sensing.

Giant Magnetoresistive (GMR) elements: GMR elements exploit the giant magnetoresistance effect, which occurs in layered structures of magnetic and non-magnetic materials. GMR sensors offer higher sensitivity and lower power consumption compared to AMR sensors. They are used in applications such as magnetic field sensing, data storage devices (read heads in hard disk drives), and magnetic field imaging.

Tunnel Magnetoresistive (TMR) elements: TMR elements utilize the tunnel magnetoresistance effect, where the electrical resistance changes based on the relative alignment of the magnetic layers separated by a thin insulating barrier. TMR sensors exhibit high sensitivity and low power consumption, making them suitable for applications such as magnetic field sensing, spintronics, and magnetic random access memory (MRAM).

Preferably, all magneto-resistors R1 to R8 are of the same type, e.g., AMR-type, GMR-type, or TMR-type.

In the context of magneto-resistive elements or magneto-resistors, “reference magnetization” refers to the orientation or alignment of the magnetic field in a specific direction that serves as a reference for measuring the changes in resistance caused by an external magnetic field. Magneto-resistors, such as AMR, GMR, or TMR magneto-resistors, exhibit a change in electrical resistance in response to the orientation of an applied external magnetic field. This change in resistance is commonly referred to as the magnetoresistance effect. To measure the magnetoresistance, a reference magnetization is established within the magneto-resistor. The reference magnetization provides a baseline against which the changes in resistance can be detected. In a typical configuration, the magneto-resistor comprises multiple layers, including magnetic layers and non-magnetic spacer layers. The reference magnetization is established within one of these layers or in an adjacent magnet or synthetic antiferromagnet. The direction of the reference magnetization remains fixed, allowing for the detection of changes in resistance caused by an external magnetic field. When an external magnetic field is applied to the magneto-resistor, the magnetization of the magneto-resistor can align or deviate from the reference magnetization, leading to a change in resistance. This change in resistance can then be measured and quantified, providing information about the magnitude, direction, or other characteristics of the external magnetic field. In summary, reference magnetization in magneto-resistors provides a fixed orientation of the magnetic field within the element, serving as a reference for measuring the changes in resistance induced by an external magnetic field. It enables the detection and quantification of magnetic field variations through the measurement of magnetoresistance.

The example of FIG. 2A shows two fully independent sensing element bridges 122-1, 122-2 with independent differential voltages V_{left}, V_{right}. The differential voltages V_{left}, V_{right} may be further fed to one or more amplifier stages 210 or further processing. This is shown in FIG. 2B. As mentioned before, the first and the second bridge circuits 122-1, 122-2 could also be implemented as half Wheatstone bridges if single-ended output signals are sufficient. Such an example is illustrated in FIG. 2C.

The sensitivity to differential magnetic fields of the architecture of FIG. 2A may be expressed as

$${V}_{diff} ( {B}_{s i g} ) = - VDDS \cdot {S}_{B} \cdot {B}_{s i g}$$

where VDDS denotes the supply voltage at the first and second power supply terminals 202-1, 202-2, S_{B} denotes the sensitivity of the bridge circuits 122-1, 122-2, and ·B_{sig} denotes the strength of the external differential magnetic field.

The sensitivity to homogeneous fields of the architectures of FIGS. 2A-2C is zero.

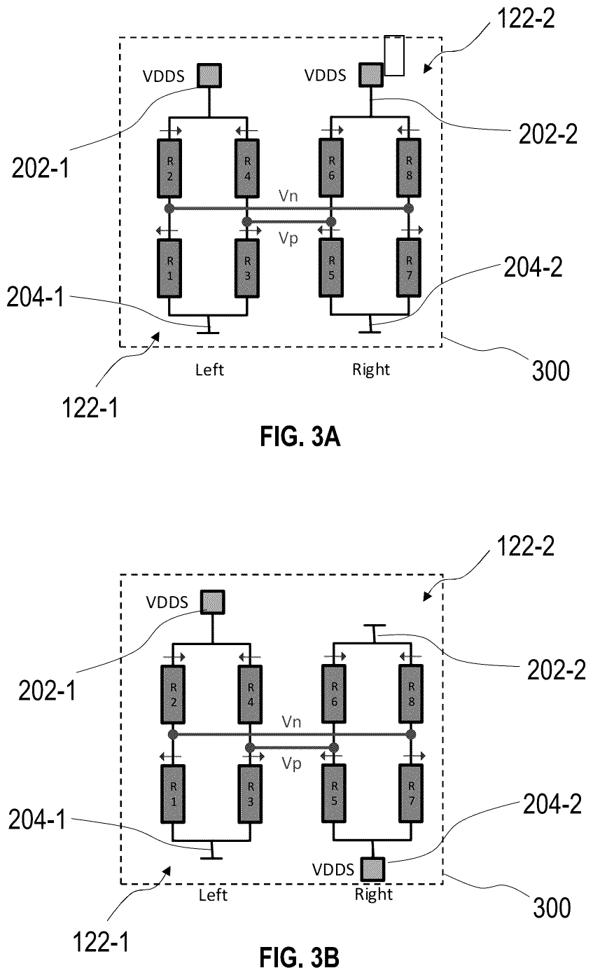

In order to provide magnetic field sensor circuits which can be used for measuring both homogeneous magnetic fields as well as differential magnetic fields, the present disclosure proposes to interconnect the two bridge circuits 122-1, 122-2. Various examples of resulting magnetic field sensor circuits are shown in FIGS. 3A to 3D.

A first implementation of a magnetic field sensor circuit 300 with interconnected bridge circuits 122-1, 122-2 is shown in FIG. 3A.

Magnetic field sensor circuit 300 of FIG. 3A differs from magnetic field sensor circuit 120 of FIG. 2A in that the first output terminal between first magneto-resistor R1 and second magneto-resistor R2 (of first bridge circuit 122-1) and the fourth output terminal between seventh magneto-resistor R7 and eighth magneto-resistor R8 (of second bridge circuit 122-2) are (directly) coupled or interconnected. In other words, the first output terminal and the fourth output terminal are short circuited. The coupled first and fourth output terminals provide a first output signal Vn of the magnetic field sensor circuit 300. Likewise the second output terminal between third magneto-resistor R3 and fourth magneto-resistor R4 (of first bridge circuit 122-1) and the third output terminal between fifth magneto-resistor R5 and sixth magneto-resistor R6 (of second bridge circuit 122-2) are (directly) coupled or interconnected. In other words, the second output terminal and the third output terminal are short circuited. The coupled second and third output terminals provide a second output signal Vp of the magnetic field sensor circuit 300. As can be seen, the branches of the different bridge circuits 122-1, 122-2 having different (antiparallel) reference magnetizations are interconnected or coupled. Again, the skilled person having benefit from the present disclosure will appreciate that the first and the second bridge circuits 122-1, 122-2 could also be implemented as (directly) coupled or interconnected half Wheatstone bridges if single-ended output signals are sufficient.

The sensitivity to differential magnetic fields of the architecture of FIG. 3A may be expressed as

$${V}_{diff} ( {B}_{s i g} ) = - \frac{V DDS \cdot {S}_{B}}{2} {B}_{s i g}$$

Thus, the sensitivity to differential fields of the architecture of FIG. 2B is half of the sensitivity to differential fields of the architecture of FIG. 2A. However, the architecture of FIG. 3A may have several advantages vis-à-vis the architecture of FIG. 2A which will become apparent in the following.

The sensitivity to homogeneous fields of the architecture of FIG. 3A may be expressed as

$${V}_{diff} ( {B}_{h o m} ) = \frac{{V}_{R} \cdot {S}_{B R} - {V}_{L} \cdot {S}_{B L}}{2} {B}_{h o m}$$

where V_{L} denotes the supply voltage at the left power supply terminal 202-1, V_{R} denotes the supply voltage at the right power supply terminal 202-2, S_{BL} denotes the sensitivity of the left bridge circuit 122-1, S_{BR} denotes the sensitivity of the right bridge circuit 122-2, and Bₕₒₘ denotes the strength of the external homogeneous magnetic field. Given that V_{R}=V_{L}=VDDS and equal sensitivities S_{BL}=S_{BR}, the sensitivity to homogeneous fields will be zero. Thus, if the sensitivities of the left and the right bridge 122-1, 122-2 are the same, the sensitivity to homogeneous fields is zero and the sensing element arrangement of FIG. 3A is only sensitive to differential fields.

To realize a homogeneous field sensor with the proposed interconnected bridge arrangement, one may flip one of the bridge power supplies to have a fully homogeneous sensor. This is shown in FIG. 3B.

Magnetic field sensor circuit 300 of FIG. 3B differs from FIG. 3A in that supply voltage VDDS of right bridge circuit 122-2 is coupled to lower terminal 204-2 and ground is coupled to upper terminal 202-2, while in FIG. 3A supply voltage VDDS is coupled to upper terminal 202-2 and ground is coupled to lower terminal 204-2. That is, the supply of right bridge circuit 122-2 is flipped with regards to FIG. 3A. In FIG. 3B, ground is directly coupled to sixth magneto-resistor R6 and eighth magneto-resistor R8, and power supply is directly coupled to fifth magneto-resistor R5 and seventh magneto-resistor R7.

The sensitivity to differential fields of the architecture of FIG. 3B may be expressed as

$${V}_{diff} ( {B}_{s i g} ) = \frac{{V}_{R} \cdot {S}_{B R} - {V}_{L} \cdot {S}_{B L}}{4} {B}_{s i g}$$

Thus, if the sensitivities of the left and the right bridge circuits 122-1, 122-2 are the same, the sensitivity to differential fields is zero and the sensing element arrangement is only sensitive to homogeneous fields.

The sensitivity to homogeneous fields of the architecture of FIG. 3B may be expressed as

$${V}_{diff} ( {B}_{h o m} ) = - \frac{V DDS \cdot {S}_{B}}{1} \cdot {B}_{h o m}$$

So if the individual bridge sensitivities of left and right bridge are the same, the differential sensitivities cancel out and only a sensitivity to homogeneous fields is left. Switches may be implemented in the supply path to switch between the sensing element arrangements of FIGS. 3A and 3B. For the purpose of flipping the supply of second bridge circuit 122-2 between FIGS. 3A and 3B, magnetic field sensor circuit 300 may comprise a switch circuit which is configured to couple lower terminal 204-2 of second bridge circuit 122-2 to the power supply and the upper terminal 202-2 of bridge circuit 122-2 to ground in a first sensing mode (homogeneous field sensing mode). Switch circuit may also be configured to couple lower terminal 204-2 of second bridge circuit 122-2 to ground and the upper terminal 202-2 of bridge circuit 122-2 to the power supply VDDS in a second sensing mode (differential field sensing mode).

A further third sensing mode will now be described with reference to FIG. 3C. Magnetic field sensor circuit 300 of FIG. 3C differs from FIGS. 3A and 3B in that ground is coupled to both upper supply terminal 202-2 as well as to lower supply terminal 204-2 of right bridge circuit 122-2, while in FIGS. 3A and 3B supply voltage VDDS is coupled to one of terminals 202-2, 204-2. In FIG. 3C, ground is directly coupled to sixth magneto-resistor R6 and eighth magneto-resistor R8, and ground is also directly coupled to fifth magneto-resistor R5 and seventh magneto-resistor R7.

By applying ground to the supply of one of the bridges 122-2, one can easily see, that the sensing arrangement is sensitive to both, differential and homogeneous fields. This grounding of one of the bridges 122-1, 122-2 is easy to implement.

The sensitivity to differential fields of the architecture of FIG. 3C may be expressed as

$${V}_{diff} ( {B}_{s i g} ) = - \frac{V DDS \cdot {S}_{B}}{4} {B}_{s i g}$$

The sensitivity to homogeneous fields of the architecture of FIG. 3C may be expressed as

$${V}_{diff} ( {B}_{h o m} ) = - \frac{V DDS \cdot {S}_{B}}{2} {B}_{h o m}$$

For the purpose of flipping the configuration of magnetic field sensor circuit 200 between FIGS. 3A to 3C, magnetic field sensor circuit 200 may comprise a switch circuit which is configured to couple both the lower terminal 204-2 and upper terminal 202-2 of second bridge circuit 122-2 to ground in a third sensing mode (differential+homogeneous field sensing mode). Switch circuit may also be configured to couple lower terminal 204-2 of second bridge circuit 122-2 to ground and the upper terminal 202-2 of bridge circuit 122-2 to the power supply VDDS in the second sensing mode (differential field sensing mode). Switch circuit may also be configured to couple lower terminal 204-2 of second bridge circuit 122-2 to the power supply voltage VDDS and the upper terminal 202-2 of bridge circuit 122-2 to ground in the first sensing mode (homogeneous field sensing mode).

The skilled person having benefit from the present disclosure will appreciate that magnetic field sensor circuits 300 of FIG. 3A, FIG. 3B, and FIG. 3C may come as standalone magnetic field sensor circuits 200 or be combined via the mentioned a switch circuitry which is configured to switch between the different magnetic field sensor circuit arrangements.

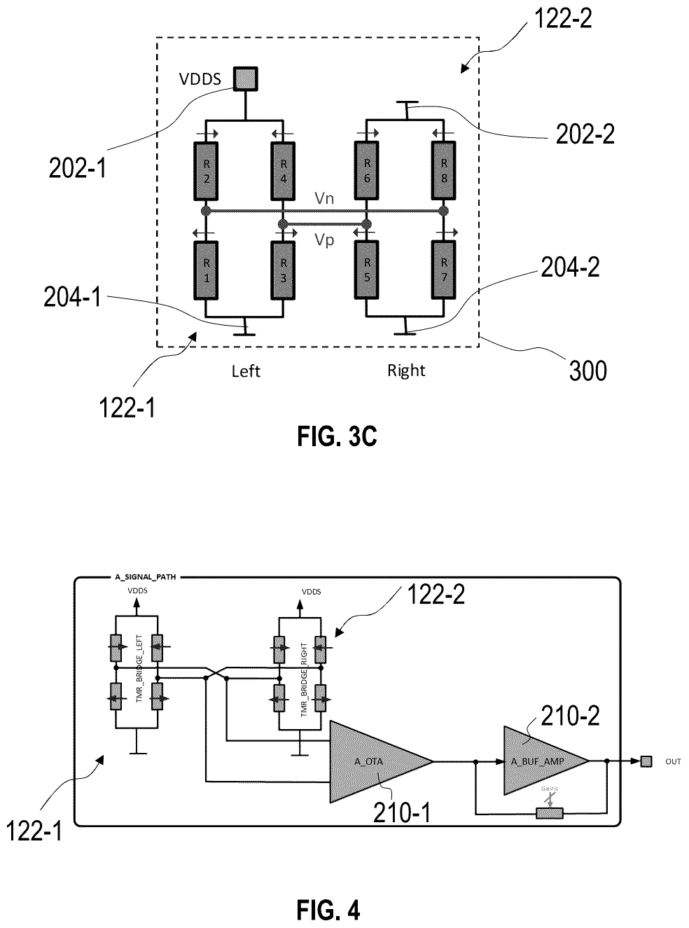

The examples of FIGS. 3A to 3C show two interconnected sensing element bridges 122-1, 122-2 with a differential output voltage (Vₐ, Vₚ) The differential output voltage may be further fed to one or more amplifier stages 210 or further processing. This is shown in FIG. 4, where a first input terminal of difference amplifier 210-1 is coupled to the first output signal (Vn) and a second input terminal of the difference amplifier 210-1 is coupled to the second output signal (Vp).

As mentioned before, the interconnected first and the second bridge circuits 122-1, 122-2 could also be implemented as half Wheatstone bridges if single-ended output signals are sufficient.

The present disclosure describes an architecture with a simple solution to generate a differential sensor or a homogeneous field sensor. This could be used in a user system to either provide the user full flexibility for selecting the same sensor for different applications and configure the sensor according to the needed measurement principle. On the other hand, one could also use this capability to measure overlayed homogeneous fields continuously and compensate for the effects of them in a differential measurement problem.

The present disclosure proposes an interconnected double bridge sensing element arrangement which allows a simple and efficient architecture of the sensor electronics in combination with the possibility to employ different operating modes on the bridge configuration.

The aspects and features described in relation to a particular one of the previous examples may also be combined with one or more of the further examples to replace an identical or similar feature of that further example or to additionally introduce the features into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A magnetic field sensor circuit, comprising:
a first bridge circuit comprising a first series connection of a first magneto-resistor and a second magneto-resistor; and
a second bridge circuit comprising a second series connection of a third magneto-resistor and a fourth magneto-resistor,
wherein a first terminal between the first magneto-resistor and the second magneto-resistor of the first bridge circuit is coupled to a second terminal between the third magneto-resistor and the fourth magneto-resistor of the second bridge circuit, and
wherein the coupled first terminal coupled to the second terminal provides a first output signal of the magnetic field sensor circuit.

2. The magnetic field sensor circuit of claim 1, wherein the first terminal and the second terminal are short circuited.

3. The magnetic field sensor circuit of claim 1, wherein:
the first series connection of the first magneto-resistor and the second magneto-resistor is coupled between a first power supply terminal and a first ground terminal,
the second series connection of the third magneto-resistor and the fourth magneto-resistor is coupled between a second power supply terminal and a second ground terminal.

4. The magnetic field sensor circuit of claim 3, wherein the first power supply terminal is coupled to a magneto-resistor of the first series connection having a first reference magnetization and the second power supply terminal is coupled to a magneto-resistor of the second series connection having a second reference magnetization that is different from the first reference magnetization.

5. The magnetic field sensor circuit of claim 4, wherein the second reference magnetization is antiparallel to the first reference magnetization.

6. The magnetic field sensor circuit of claim 3, wherein the first power supply terminal is coupled to a magneto-resistor of the first series connection having a first reference magnetization and the second power supply terminal is coupled to a magneto-resistor of the second series connection having the first reference magnetization.

7. The magnetic field sensor circuit of claim 1, wherein:
the first series connection of the first magneto-resistor and the second magneto-resistor is coupled between a first power supply terminal and a first ground terminal, and
the second series connection of the third magneto-resistor and the fourth magneto-resistor is coupled between a second ground terminal and a third ground terminal.

8. The magnetic field sensor circuit of claim 1, wherein the first series connection of the first magneto-resistor and the second magneto-resistor is coupled between a power supply terminal and a ground terminal, and wherein the magnetic field sensor circuit further comprises:
a switch circuit configured to switch between different sensing modes by modifying a power supply of the first series connection or the second series connection.

9. The magnetic field sensor circuit of claim 8, wherein the switch circuit is configured to;
in a first sensing mode, couple the second series connection of the third magneto-resistor and the fourth magneto-resistor between the power supply terminal and the ground terminal;
in a second sensing mode, switch the power supply terminal and the ground terminal for the second series connection compared to the first sensing mode; or
in a third sensing mode, couple the second series connection of the third magneto-resistor and the fourth magneto-resistor between two ground terminals.

10. The magnetic field sensor circuit of claim 1, wherein the first series connection of the first magneto-resistor and the second magneto-resistor is coupled between a power supply terminal and a ground terminal, wherein the magnetic field sensor circuit further comprises:
a switch circuit configured to;
in a first sensing mode, couple the second series connection of the third magneto-resistor and the fourth magneto-resistor between the power supply terminal and the ground terminal;
in a second sensing mode, switch the power supply terminal and the ground terminal for the second series connection compared to the first sensing mode; or
in a third sensing mode, couple the second series connection of the third magneto-resistor and the fourth magneto-resistor between two ground terminals.

11. The magnetic field sensor circuit of claim 1, wherein:
the first magneto-resistor of the first bridge circuit comprises a first reference magnetization,
the second magneto-resistor of the first bridge circuit comprises a second reference magnetization that is different from the first reference magnetization,
the third magneto-resistor of the second bridge circuit comprises the second reference magnetization, and
the fourth magneto-resistor of the second bridge circuit comprises the first reference magnetization.

12. The magnetic field sensor circuit of claim 11, wherein the second reference magnetization is antiparallel to the first reference magnetization.

13. The magnetic field sensor circuit claim 1, wherein:
the first bridge circuit comprises a third series connection of a fifth magneto-resistor and a sixth magneto-resistor connected in parallel to the first series connection,
the second bridge circuit comprises a fourth series connection of a seventh magneto-resistor and an eighth magneto-resistor connected in parallel to the second series connection,
a third terminal between the fifth magneto-resistor and the sixth magneto-resistor of the first bridge circuit is coupled to a fourth terminal between the seventh magneto-resistor and the eighth magneto-resistor of the second bridge circuit, and
wherein the coupled third terminal and the fourth terminal provide a second output signal of the magnetic field sensor circuit.

14. The magnetic field sensor circuit of claim 13, wherein the third terminal and the fourth terminal are short circuited.

15. The magnetic field sensor circuit of claim 13, wherein:
the fifth magneto-resistor of the first bridge circuit comprises the second reference magnetization,
the sixth magneto-resistor of the first bridge circuit comprises the first reference magnetization,
the seventh magneto-resistor of the second bridge circuit comprises the first reference magnetization, and
the eighth magneto-resistor of the second bridge circuit comprises the second reference magnetization.

16. The magnetic field sensor circuit of claim 13, further comprising
a difference amplifier, wherein:
a first input terminal of the difference amplifier is coupled to the first output signal, and
a second input terminal of the difference amplifier is coupled to the second output signal.

17. The magnetic field sensor circuit of claim 1, wherein the first magneto-resistor and the second magneto resistor of the first bridge circuit and third magneto-resistor and the fourth magneto-resistor of the second bridge circuit are Giant Magneto-resistors or Tunnel Magneto-resistors.

18. A m method, comprising:
providing a first bridge circuit of a magnetic field sensor circuit comprising a first series connection of a first magneto-resistor and a second magneto-resistor;
providing a second bridge circuit comprising of the magnetic field sensor circuit a second series connection of a third magneto-resistor and a fourth magneto-resistor;
coupling a first terminal between the first magneto-resistor and the second magneto-resistor of the first bridge circuit to a second terminal between the third magneto-resistor and the fourth magneto-resistor of the second bridge circuit; and
providing an output signal of the magnetic field sensor circuit at the coupled first terminal and the second terminal.

19. The method of claim 18, wherein the first bridge circuit comprises a third series connection of a fifth magneto-resistor and a sixth magneto-resistor connected in parallel to the first series connection and the second bridge circuit comprises a fourth series connection of a seventh magneto-resistor and an eighth magneto-resistor connected in parallel to the second series connection, the method further comprising:
coupling a third terminal between the fifth magneto-resistor and the sixth magneto-resistor of the first bridge circuit to a fourth terminal between the seventh magneto-resistor and the eighth magneto-resistor of the second bridge circuit; and
providing a second output signal of the magnetic field sensor circuit at the coupled third terminal and the fourth terminal.

20. The method of claim 18, further comprising:
coupling the first series connection of the first magneto-resistor and the second magneto-resistor between a power supply and a ground; and
switching between different sensing modes by modifying a power supply of the first series connection or the second series connection.

21. (canceled)
